(19) United States
(12) Patent Application Publication
(10) Pub. No.: US 2025/0359459 A1
(43) Pub. Date: Nov. 20, 2025

(54) DISPLAY DEVICE

(71) Applicant: Japan Display Inc., Tokyo (JP)

(72) Inventor: Nobuto MANAGAKI, Tokyo (JP)

(73) Assignee: Japan Display Inc., Tokyo (JP)

(21) Appl. No.: 19/185,345

(22) Filed: Apr. 22, 2025

(30) Foreign Application Priority Data
May 20, 2024 (JP) 2024-081819

(51) Int. Cl. H10K 59/00; H10K 59/35; H10K 101/20; H10K 101/40; H10K 102/00

(52) U.S. Cl. CPC H10K 59/771; H10K 59/35; H10K 2101/20; H10K 2101/40; H10K 2102/351

(57) ABSTRACT

A display device includes a first pixel, a second pixel, and a third pixel respectively including first, second, and third light-emitting elements configured to emit red light, green light, and blue light, respectively. Each of the first light-emitting element, the second light-emitting element, and the third light-emitting element includes a pixel electrode, an electron-blocking layer over the pixel electrode, an emission layer over the electron-blocking layer, a hole-blocking layer over the emission layer, and a counter electrode over the hole-blocking layer. The third light-emitting element further includes a first buffer layer between the emission layer and the hole-blocking layer. The emission layers of the first light-emitting element and the second light-emitting element include a thermally activated delayed-fluorescence material. The emission layer of the third light-emitting element includes a first fluorescence material having a fluorescence lifetime equal to or longer than 1 ps and shorter than 1 ns.

### CROSS-REFERENCE TO RELATED APPLICATIONS

This application claims the benefit of priority to Japanese Patent Application No. 2024-081819, filed on May 20, 2024, the entire contents of which are incorporated herein by reference.

### FIELD

An embodiment of the present invention relates to a display device having an electroluminescence element.

### BACKGROUND

In recent years, display devices having organic electroluminescence elements (OLEDs) have been widely used. In addition, organic electroluminescence elements exhibiting thermally activated delayed fluorescence or hyper-fluorescence (registered trademark) have attracted much attention due to their extremely high emission efficiency, and vigorous research and development have been conducted (see, for example, Japanese laid-open patent applications No. 2021-048366, 2020-013695, and 2017-222820).

### SUMMARY

An embodiment of the present invention is a display device. The display device includes a first pixel, a second pixel, and a third pixel respectively including a first light-emitting element, a second light-emitting element, and a third light-emitting element configured to emit red light, green light, and blue light, respectively. Each of the first light-emitting element, the second light-emitting element, and the third light-emitting element includes a pixel electrode, an electron-blocking layer over the pixel electrode, an emission layer over the electron-blocking layer, a hole-blocking layer over the emission layer, and a counter electrode over the hole-blocking layer. The third light-emitting element further includes a first buffer layer between the emission layer and the hole-blocking layer. The emission layers of the first light-emitting element and the second light-emitting element include a thermally activated delayed-fluorescence material. The emission layer of the third light-emitting element includes a first fluorescence material having a fluorescence lifetime equal to or longer than 1 ps and shorter than 1 ns.

An embodiment of the present invention is a light-emitting element configured to emit blue light. The light-emitting element includes a pixel electrode, an electron-blocking layer over the pixel electrode, an emission layer over the electron-blocking layer, a buffer layer over the emission layer, a hole-blocking layer over the buffer layer, and a counter electrode over the hole-blocking layer. The emission layer contains a fluorescence material having a fluorescence lifetime equal to or longer than 1 ps and shorter than 1 ns.

### BRIEF DESCRIPTION OF DRAWINGS

FIG. 1 is a schematic top view of a display device according to an embodiment of the present invention.

FIG. 2 is a schematic top view of a display device according to an embodiment of the present invention.

FIG. 3 is a schematic top view of a display device according to an embodiment of the present invention.

FIG. 4 is a schematic cross-sectional view of light-emitting elements disposed in pixels of a display device according to an embodiment of the present invention.

FIG. 5 is a schematic cross-sectional view of a display device according to an embodiment of the present invention.

FIG. 6 is a schematic cross-sectional view of light-emitting elements disposed in pixels of a display device according to an embodiment of the present invention.

FIG. 7 shows voltage-current density curves of the red-emissive light-emitting elements fabricated in the Examples.

FIG. 8 is a plot showing a relationship between the thickness of the first buffer layer and the driving voltage of the red-emissive light-emitting elements fabricated in the Examples.

FIG. 9 is a plot showing a relationship between the thickness of the first buffer layer and the current efficiency of the red-emissive light-emitting elements fabricated in the Examples.

FIG. 10 shows current density-normalized external current efficiency curves of the red-emissive light-emitting elements fabricated in the Examples.

FIG. 11 shows voltage-capacitance curves of the red-emissive light-emitting elements of the Comparative Examples.

FIG. 12 shows voltage-capacitance curves of the red-emissive light-emitting elements of the Examples.

FIG. 13 shows voltage-current density curves of the blue-emissive light-emitting elements fabricated in the Examples.

FIG. 14 is a plot showing a relationship between the thickness of the second buffer layer and the driving voltage of the blue-emissive light-emitting elements fabricated in the Examples.

FIG. 15 is a plot showing a relationship between the thickness of the second buffer layer and the current efficiency of the blue-emissive light-emitting elements fabricated in the Examples.

FIG. 16 shows current density-normalized external current efficiency curves of the blue-emissive light-emitting elements fabricated in the Examples.

FIG. 17 shows voltage-capacitance curves of the blue-emissive light-emitting elements fabricated in the Examples.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, the drawings are only an example, and do not limit the interpretation of the invention. In the specification and the drawings, the same reference number is provided to an element that is the same as that which appears in preceding drawings, and a detailed explanation may be omitted as appropriate.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

In the present invention, when one film is processed to form a plurality of films, these films may have different functions and roles. However, these films originate from the film prepared as the same layer by the same process and have substantially the same layer structure, material, and morphology. Hence, the plurality of films is defined as existing in the same layer.

Hereinafter, a display device 100 according to an embodiment of the present invention is explained.

### 1. Overall Structure

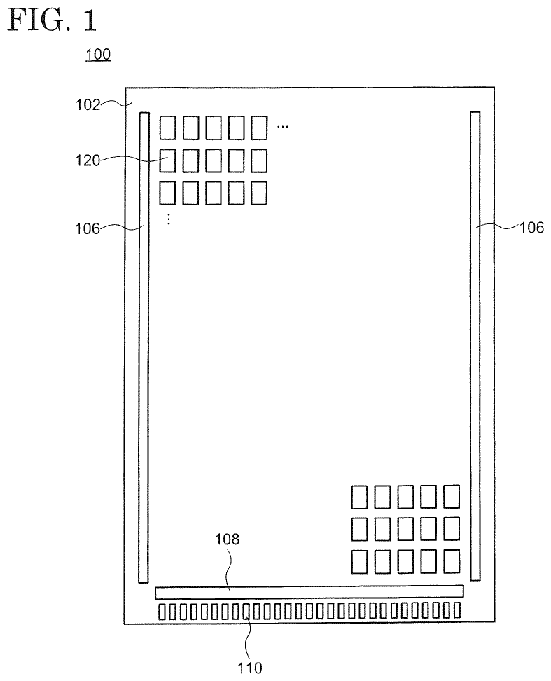

A schematic top view of the display device 100 is shown in FIG. 1. As shown in FIG. 1, the display device 100 has a substrate 102 and a counter substrate which is not illustrated in FIG. 1, between which a variety of patterned insulating films, semiconductor films, and conductor films is stacked. Appropriate stacking of these films leads to the formation of a plurality of pixels 120 and driver circuits for driving the pixels 120 (scanning-line driver circuit 106 and signal-line driver circuit 108) over the substrate 102. The substrate 102 and the counter substrate are secured by a sealing material or the like (not illustrated), thereby encapsulating and protecting the pixels 120, the scanning-line driver circuit 106, and the signal-line driver circuit 108. A plurality of terminals 110 formed with conductor films is provided over the substrate 102, and the terminals 110 are electrically connected to an external circuit which is not illustrated via a connector such as a flexible printed circuit (FPC) board. A variety of signals and power for displaying images are supplied from the external circuit to the scanning-line driver circuit 106 and the signal-line driver circuit 108 via the terminals 110. Note that one or both of the scanning-line driver circuit 106 and the signal-line driver circuit 108 need not be formed directly over the substrate 102, but a driver circuit formed over a substrate different from the substrate 102 (such as a semiconductor substrate) may be disposed over the substrate 102 or the connector as the scanning-line driver circuit 106 and/or the signal-line driver circuit 108.

A pixel circuit is formed in each pixel 120, and one of the light-emitting elements providing the three primary colors (i.e., a red-emissive light-emitting element, a green-emissive light-emitting element, and a blue-emissive light-emitting element) is further arranged. Signals to operate the pixel circuits are generated by the scanning-line driver circuit 106 and the signal-line driver circuit 108 on the basis of a variety of signals supplied from the external circuit and are supplied to each pixel 120. As a result, the light-emitting elements connected to the pixel circuits emit light, allowing each pixel 120 to function as the smallest unit providing color information. Accordingly, full-color display is possible. Here, a red-emissive light-emitting element, a green-emissive light-emitting element, and a blue-emissive light-emitting element are, for example, elements exhibiting an emission peak wavelength in the range equal to or longer than 650 nm and equal to or shorter than 750 nm, equal to or longer than 500 nm and equal to or shorter than 650 nm, and equal to or longer than 400 nm and equal to or shorter than 500 nm, respectively.

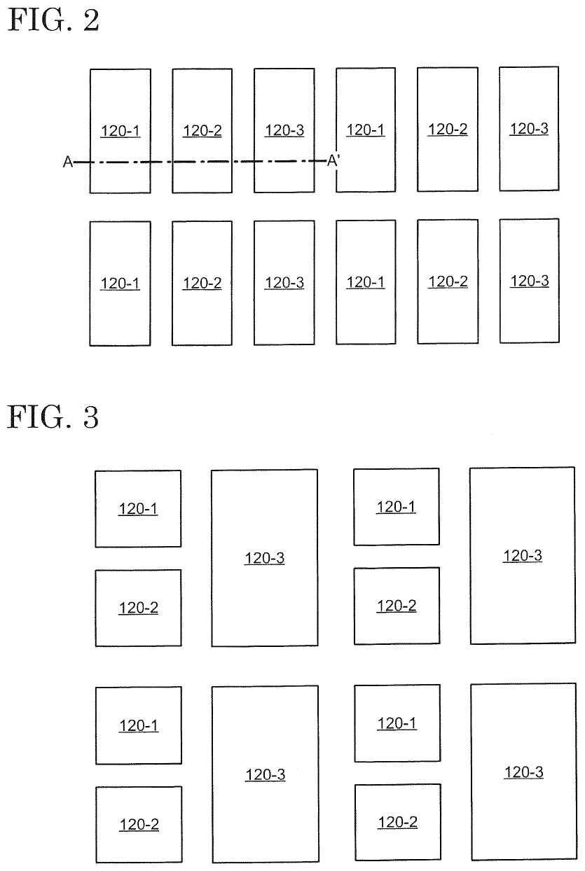

There are no restrictions on the arrangement of the pixels 120. For example, a stripe arrangement may be adopted in which the red-emissive light-emitting element 120-1, the green-emissive light-emitting element 120-2, and the blue-emissive light-emitting element 120-3 respectively providing red color, green color, and blue color are sequentially arranged in the row direction, and the pixels 120 providing the same emission color are arranged in the same column as shown in FIG. 2. Alternatively, although not illustrated, a variety of arrangements such as a delta arrangement and a pentile arrangement may be employed in addition to a mosaic arrangement in which the red-emissive pixel 120-1, the green-emissive pixel 120-2, and the blue-emissive pixel 120-3 are sequentially arranged in both the row direction and the column direction. Alternatively, the plurality of pixels 120 may be arranged so that one or more red-emissive pixels 120-1 and one or more green-emissive pixels 120-2 are sandwiched between adjacent blue-emissive pixels 120-3 as shown in FIG. 3. Here, the burden on the blue-emissive light-emitting elements can be reduced and the reliability of the display device 100 can be improved by arranging the plurality of pixels 120 so that the blue-emissive pixel 120-3 in which the blue-emissive light-emitting element with the lowest emission efficiency is arranged has a larger area than the other pixels 120.

### 2. Structure of Light-Emitting Element

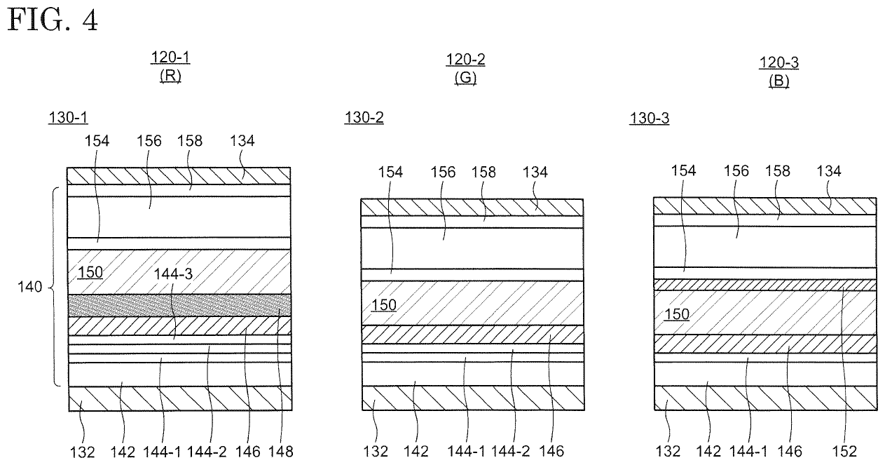

The light-emitting elements provided in the red-emissive pixel 120-1, the green-emissive pixel 120-2, and the blue-emissive pixel 120-3 are explained using FIG. 4. The light-emitting elements 130 disposed in each pixel 120 are so-called organic electroluminescence elements, and each have a pair of electrodes (pixel electrode 132 and counter electrode 134) and an electroluminescence layer (hereinafter, referred to as an EL layer) 140 provided between the pixel electrode 132 and the counter electrode 134. The EL layer 140 is a laminated body of a plurality of functional layers including at least an electron-blocking layer 146, an emission layer 150, a hole-blocking layer 154, and a second buffer layer 152. In addition to these layers, the functional layers may also include a hole-injection layer 142, a hole-transporting layer 144, a first buffer layer 148, an electron-transporting layer 156, an electron-injection layer 158, and the like.

### (1) Pixel Electrode and Counter Electrode

The pixel electrode 132 is provided individually in each pixel 120 and functions as an electrode for injecting holes into the EL layer 140 in each pixel 120. When the light obtained in the EL layer 140 is extracted through the pixel electrode 132, the pixel electrode 132 is configured to transmit visible light. Thus, the pixel electrode 132 is composed of a conductive oxide transmitting visible light, such as indium-tin oxide (ITO) and indium-zinc oxide (IZO). On the other hand, when the light is extracted through the counter electrode 134, the pixel electrode 132 is configured to function as a reflective electrode efficiently reflecting light. In this case, the pixel electrode 132 is configured to include a metal with high reflectivity, such as silver, aluminum, and an alloy thereof. For example, a configuration in which a film containing a metal is covered or sandwiched by a film containing a conductive oxide may be applied to the pixel electrode 132.

The counter electrode 134 is an electrode for injecting electrons into the EL layer 140. When the light obtained in the EL layer 140 is extracted through the pixel electrode 132, the counter electrode 134 also functions as a reflecting electrode. Thus, the counter electrode 134 is configured to contain the metal or the alloy described above (for example, an alloy of silver and a metal with a low work function such as magnesium). Conversely, when the light obtained in the EL layer 140 is extracted through the counter electrode 134, the counter electrode 134 is configured to include a conductive oxide transmitting visible light. Alternatively, a metal-containing film (e.g., a film including magnesium, an alloy of magnesium and silver, or the like) having a thickness (e.g., equal to or greater than 5 nm and equal to or less than 20 nm) allowing visible light to pass therethrough may be used as the counter electrode 134. In the latter case, a film of a conductive oxide transmitting visible light may be further provided over the metal-containing film. Unlike the pixel electrode 132, the counter electrode 134 is provided to be shared by the plurality of pixels 120 (e.g., all of the pixels 120 of the display device 100). Therefore, the counter electrode 134 is not divided but is continuous between the pixels 120.

### (2) Hole-Injection Layer

The hole-injection layer 142 functions to promote hole injection from the pixel electrode 132 to the EL layer 140. A compound to which holes are easily injected, i.e., easily oxidized (electron-donating) may be used for the hole-injection layer 142. In other words, a compound with a shallow highest occupied molecular orbital (HOMO) level can be used. For example, an aromatic amine such as a benzidine derivative and a triarylamine, a carbazole derivative, a thiophene derivative, a phthalocyanine derivative such as copper phthalocyanine, and the like may be used. Alternatively, a polymeric material such as a polythiophene, a polyaniline, and their derivatives may be used, and poly(ethylenedioxythiophene)/poly(styrenesulfonic acid) is represented as an example. A mixture of an electron-donating compound such as the aforementioned aromatic amines and carbazole derivatives or an aromatic hydrocarbon with an electron acceptor may be used. Examples of an electron acceptor include a transition metal oxide such as vanadium oxide and molybdenum oxide, a nitrogen-containing heteroaromatic compound, an aromatic compound with a strong electron-withdrawing group such as a cyano group, and the like. The hole-injection layer 142 may have a single-layer structure or may be composed of a plurality of layers containing different materials. The hole-injection layer 142 may also be provided to be shared by multiple pixels 120 (e.g., all of the pixels 120 of the display device 100). In this case, the hole-injection layer 142 exists in the same layer between the pixels 120 (i.e., light-emitting elements 130) and is continuous without being divided between the pixels 120 (light-emitting elements 130).

### (3) Hole-Transporting Layer

The hole-transporting layer 144 is provided over and in contact with the hole-injection layer 142. The hole-transporting layer 144 has a function of transporting holes injected into the hole-injection layer 142 to the emission layer 150, and the same or similar materials as those which can be used in the hole-injection layer 142 may be used. For example, a material with a deeper HOMO level than the hole-injection layer 142 but with a difference of about 0.5 eV or less can be used. Typically, an aromatic amine such as a benzidine derivative may be used. The hole-transporting layer 144 may also have a single-layer structure or may be composed of a plurality of layers containing different materials.

The hole-transporting layer 144 may also be provided to be shared by the plurality of pixels 120 (e.g., all of the pixels 120 of the display device 100). In this case, the hole-transporting layer 144 exists in the same layer between the pixels 120 (i.e., light-emitting elements 130) and is continuous without being divided between the pixels 120 (light-emitting element 130).

The hole-transporting layer 144 may be formed so that the thickness thereof is the same or different between the pixels 120. In the latter case, the hole-transporting layer 144 is preferably provided so that the thickness increases in the order of the blue-emissive pixel 120-3, the green-emissive pixel 120-2, and the red-emissive pixel 120-1. While the light obtained from the light-emitting layer 150 travels isotropically and is extracted from the pixel electrode 132 and/or the counter electrode 134, the light is repeatedly reflected between the pixel electrode 132 and the counter electrode 134. Therefore, the pixel electrode 132 and the counter electrode 134 form a resonator structure. Hence, the obtained light can be amplified by the resonance to increase the luminance of the display device 100 in the frontal direction by appropriately adjusting the distance between the pixel electrode 132 and the counter electrode 134. Since the distance required for resonance (optical distance) increases as the wavelength increases, it is possible to form the appropriate resonator structure in each pixel 120 by increasing the thickness of the hole-transporting layer 144 in the order of the blue-emissive pixel 120-3, the green-emissive pixel 120-2, and the red-emissive pixel 120-1.

Therefore, a first hole-transporting layer 144-1 is formed with the same thickness so as to be shared by all of the pixels 120 as shown in FIG. 4, for example. Furthermore, a second hole-transporting layer 144-2 is formed over the first hole-transporting layer 144-1 in the green-emissive pixel 120 and the red-emissive pixel 120-1 with the same thickness so as to be shared by the green-emissive pixel 120 and the red-emissive pixel 120-1. Furthermore, a third hole-transporting layer 144-3 may be formed over the second hole-transporting layer 144-2 in the red-emissive pixel 120-1. This process allows the thickness of the hole-transporting layer 144 to increase according to the increase in the emission wavelength. Although the first hole-transporting layer 144-1, the second hole-transporting layer 144-2, and the third hole-transporting layer 144-3 may have the same composition or different compositions, the display device 100 can be efficiently manufactured by employing the same composition in these layers.

### (4) Electron-Blocking Layer

The electron-blocking layer 146 is provided over and in contact with the hole-transporting layer 144. The electron-blocking layer 146 has a function to confine the electrons injected from the counter electrode 134 within the emission layer 150 by preventing the electrons from passing through the emission layer 150 without contributing to recombination within the emission layer 150 and being injected into the hole-transporting layer 144 and also has a function of preventing the excitation energy obtained in the emission layer 150 from being transferred to the molecules of the hole-transporting layer 144. These functions prevent a decrease in emission efficiency.

It is preferable to use a material in the electron-blocking layer 146 which has higher or comparative hole transport properties than electron transport properties as well as a shallower lowest unoccupied molecular orbital (LUMO) level and a larger band gap than the molecules in the emission layer 150. Specifically, a difference between the LUMO level of the molecules included in the electron-blocking layer 146 and that of the molecules included in the emission layer 150 is preferable to be equal to or greater than 0.2 eV, 0.3 eV, or 0.5 eV. Moreover, the difference between the band gap of the molecules in the electron-blocking layer 146 and that of the molecules in the emission layer 150 is preferred to be equal to or greater than 0.2 eV, 0.3 eV, or 0.5 eV. Specifically, an aromatic amine derivative, a carbazole derivative, a 9,10-dihydroacridine derivative, a benzofuran derivative, a benzothiophene derivative, and the like can be used in the electron-blocking layer 146. The electron-blocking layer 146 may also have a single-layer structure or may be composed of a plurality of layers containing different materials.

The electron-blocking layer 146 may also be provided so as to be shared by the plurality of pixels 120 (e.g., all of the pixels 120 of the display device 100). In this case, the electron-blocking layer 146 exists in the same layer between the pixels 120 (i.e., light-emitting elements 130) and is continuous without being divided between the pixels 120 (light-emitting elements 130). The electron-blocking layer 146 has the same composition and thickness between the pixels 120 (light-emitting elements 130).

### (5) First Buffer Layer

The first buffer layer 148 can be selectively provided in the red-emissive light-emitting element 130-1 arranged in the red-emissive pixel 120-1. The first buffer layer 148 is a functional layer for adjusting the carrier balance of the red-emissive light-emitting element 130-1 and is provided in direct contact with the electron-blocking layer 146 and the emission layer 150. The first buffer layer 148 includes the host material included in the emission layer 150. In other words, in the red-emissive light-emitting element 130-1, the material included in the first buffer layer 148 is identical to the host material included in the emission layer 150. Preferably, the first buffer layer 148 consists of the host material and is substantially free of other components. The thickness of the first buffer layer 148 is relatively small and is, for example, equal to or greater than 2.0 nm and equal to or less than nm or equal to or greater than 2.0 nm and equal to or less than 8.5 nm. As described below, the use of the first buffer layer 148 enables the construction of an excellent carrier balance in the red-emissive light-emitting element 130-1, by which a high emission efficiency and low driving voltage can be realized. In addition, since an excellent carrier balance can be obtained even if many functional layers (e.g., hole-blocking layer 154, electron-blocking layer 146, electron-transporting layer 156, and the like) are formed to be shared by all of the pixels 120, the number of deposition masks for manufacturing the display device 100 can be reduced, which enables the production of display devices at a lower cost.

### (6) Emission Layer

### (a) Emission Layer of Blue-Emissive Light-Emitting Element

The emission layer 150 provided in the blue-emissive light-emitting element 130-3 contains a host material as the main component and a blue-emissive fluorescence material responsible for light emission. The volume ratio of the host material to the emission material (emission material/host material) may be, for example, equal to or greater than 0.01 and equal to or less than 0.20. As the host material, an oxadiazole derivative, a triazole derivative, a benzimidazole derivative, a quinoxaline derivative, a dibenzoquinoxaline derivative, a dibenzothiophene derivative, a dibenzofuran derivative, a pyrimidine derivative, a triazine derivative, a pyridine derivative, a bipyridine derivative, a phenanthroline derivative, an aromatic amine derivative, a carbazole derivative, and the like can be used in addition to a zinc or aluminum-based metal complex, for example. Here, a blue emission is an emission whose maximum emission peak wavelength is located in the range equal to or longer than 400 nm and equal to or shorter than 500 nm.

As the emission material, a blue-emissive fluorescence material which does not exhibit thermally activated delayed fluorescence (TADF) is used. Specifically, a fluorescence material with a maximum emission peak wavelength located in the range equal to or longer than 400 nm and equal to or shorter than 500 nm and a fluorescence lifetime equal to or longer than 10⁻⁹ seconds (1 ps) and shorter than 10-6 seconds (1 ns) is used. For example, an anthracene derivative, a stilbene derivative, a pyrene derivative, and the like are exemplified as the fluorescence material.

### (b) Emitting Layers of Red- and Green-Emissive Light-Emitting Elements

Similar to the blue-emissive light-emitting element 130-3, the emission layers 150 provided in the red-emissive light-emitting element 130-1 and the green-emissive light-emitting element 130-2 also contain a host material as the main component as well as an emission material responsible for light emission. However, unlike the blue-emissive light-emitting element 130-3, a red-emissive material and a green-emissive material which exhibit thermally activated delayed fluorescence (thermally activated delayed fluorescence material) are used as the emission material in the red-emissive light-emitting element 130-1 and the green-emissive light-emitting element 130-2, respectively. The concentration of the emission material, i.e., thermally activated delayed fluorescence material, in the emission layer is also relatively high, and the volume ratio of the host material to the emission material (emission material/host material) is set to be equal to or greater than 0.30 and equal to or less than 0.60, for example. Here, a green emission is an emission whose maximum peak emission wavelength is located in the range equal to or longer than 500 nm and equal to or shorter than 650 nm, while a red emission is an emission whose maximum peak emission wavelength is located in the range equal to or longer than 650 nm and equal to or shorter than 750 nm. In a thermally activated delayed fluorescence material, the difference between the triplet excitation energy level and the singlet excitation energy level is small and is, for example, equal to or greater than 5 meV and equal to or less than 20 meV. Therefore, the triplet excited state of the emission material produced by carrier recombination is able to undergo intersystem crossing to the singlet excited state by extremely low thermal energy such as room temperature or lower. As a result, the rate of thermal deactivation of the triplet excited state is relatively low, and radiative deactivation from the singlet excited state is promoted. Due to this mechanism, a thermally activated delayed fluorescence material emits light with a remarkably long lifetime while having a spectrum similar to that of normal fluorescence. The fluorescence lifetime of a thermally activated delayed fluorescence material is equal to or longer than 10⁻⁶ seconds (1 ns), preferably equal to or longer than 10⁻³ seconds (1 μs). Since the probability of formation of the triplet excited state generated by recombination of holes and electrons is about three times that of the singlet excited state, the efficiency of the light-emitting element 130 can be dramatically improved by using a thermally activated delayed fluorescence material.

Examples of thermally activated delayed fluorescence materials include a fullerene and its derivatives, an acridine derivative such as proflavine, an eosin, and the like. Furthermore, metal-containing porphyrins containing magnesium, zinc, cadmium, tin, platinum, indium, or palladium are represented. Metal-containing porphyrins include, for example, protoporphyrin-tin fluoride complexes, a mesoporphyrin-tin fluoride complex, a hematoporphyrin-tin fluoride complex, a coproporphyrin tetramethyl ester-tin fluoride complex, an octaethylporphyrin-tin fluoride complex, an ethioporphyrin-tin fluoride complex, an octaethylporphyrin-platinum chloride complex, and the like.

In addition, a compound in which an electron-donor component and an electron-acceptor component are linked may be used. As the electron-donor component and the electron-acceptor component, a TT-electron-excessive heteroaromatic ring and a IT-electron-deficient heteroaromatic ring are represented, respectively. The fundamental skeleton of the TT-electron-deficient heteroaromatic ring includes a pyridine skeleton, a diazine skeleton, a triazine skeleton, and the like. The fundamental skeleton of the TT-electron-excessive heteroaromatic ring includes an acridine skeleton, a phenoxazine skeleton, a phenothiazine skeleton, a furan skeleton, a thiophene skeleton, a pyrrole skeleton, and the like. Such compounds include 2-(biphenyl-4-yl)-4,6-bis(12-phenylindolo [2,3-a]carbazole-11-yl)-1,3,5-triazine, 9-(4,6-diphenyl-1,3,5-triazine-2-yl)-9′-phenyl-9H,9′H-3,3′-bicarbazole, 9-[4-(4,6-diphenyl-1,3,5-triazine-2-yl)phenyl]-9′-phenyl-9H,9H-3,3′-bicarbazol, 2-[4-(10H-phenoxazin-10-yl)phenyl]-4,6-diphenyl-1,3,5-triazine, and the like.

Both or one of the emission layers 150 provided in the red-emissive light-emitting element 130-1 and the green-emissive light-emitting element 130-2 may further include, as an emission material, a fluorescence material capable of receiving the singlet excitation energy of the thermally activated delayed fluorescence material to form a singlet excited state (hereinafter, also referred to as a second fluorescence material) in addition to the thermally activated delayed fluorescence material. The second fluorescence material is selected such that the energy level of its singlet excited state is lower than that of the thermally activated delayed fluorescence material and its band gap is smaller than that of the thermally activated delayed fluorescence material. The second fluorescence material does not exhibit thermally activated delayed fluorescence in the red-emissive light-emitting element 130-1 and the green-emissive light-emitting element 130-2, and thus exhibits a relatively short fluorescence lifetime (e.g., equal to or longer than 1 ps and shorter than 1 ns). Specifically, a fluorescence material such as a coumarin derivative, a pyran derivative, a quinacridone derivative, a tetracene derivative, a pyrene derivative, an anthracene derivative, a pyran derivative, and the like are exemplified. In general, the emission spectrum exhibited by thermally activated delayed fluorescence materials is broad and has low color purity. In contrast, the fluorescence materials described above provide an emission spectrum with a relatively narrow full width at half maximum, and thus is capable of emitting light with high color purity. Therefore, the light-emitting element 130 exhibiting not only excellent color purity but also a high emission efficiency resulting from the thermally activated delayed fluorescence material can be provided by further adding the second fluorescence material to the emission layer 150. As a result, a display device with high color reproducibility can be provided.

### (7) Second Buffer Layer

The second buffer layer 152 is not provided in the red-emissive pixel 120-1 and the green-emissive pixel 120-2, but is selectively provided in the blue-emissive light-emitting element 130-3 of the blue-emissive pixel 120-3. The second buffer layer 152 is a functional layer for adjusting the carrier balance of the blue-emissive light-emitting element 130-3 and is provided in direct contact with the emission layer 150 and the hole-blocking layer 154. The thickness of the second buffer layer 152 is relatively small and is preferably equal to or greater than 2 nm and equal to or less than 8.5 nm or equal to or greater than 2 nm and equal to or less than 5 nm. The second buffer layer 152 creates an appropriate energy barrier between the hole-blocking layer 154 and the emission layer 150 to improve the carrier balance in the blue-emissive light-emitting element 130-3, resulting in an increased efficiency, a reduced driving voltage, and an improved lifetime.

Specifically, the second buffer layer 152 is configured so that the difference in LUMO level between the second buffer layer 152 and the hole-blocking layer 154 is equal to or greater than 0.1 eV and equal to or less than 0.3 eV and the difference in LUMO level between the second buffer layer 152 and the emission layer 150 is equal to or greater than 0.1 eV and equal to or less than 0.3 eV. Moreover, the second buffer layer 152 is configured so that the difference in HOMO level between the second buffer layer 152 and the hole-blocking layer 154 is equal to or greater than 0.1 eV and equal to or less than 0.3 eV and the difference in HOMO level between the second buffer layer 152 and the emission layer 150 is equal to or greater than 0.1 eV and equal to or less than 0.3 eV. For example, the aforementioned host material usable for the blue-emissive light-emitting element 130-3 or a material usable in the hole-blocking layer 154 described below, which satisfy the aforementioned relationship with respect to the HOMO level and the LUMO level, may be selected.

Alternatively, the second buffer layer 152 may substantially consist of the host material contained in the emission layer 150 of the blue-emissive light-emitting element 130-3 and may contain substantially no other components. In this case, since the second buffer layer 152 does not contain an emission material with a smaller band gap than the second buffer layer 152, the hole- and electron-injection characteristics decrease compared with the emission layer 150. As a result, the second buffer layer 152 is able to act as a resistance component between the hole-blocking layer 154 and the emission layer 150.

(8) Hole-Blocking layer

The hole-blocking layer 154 has a function to confine the holes injected from the pixel electrode 132 within the emission layer 150 by preventing the holes from passing through the emission layer 150 without contributing to recombination and being injected into the electron-transporting layer 156 as well as a function to prevent the excitation energy obtained in the emission layer 150 from being transferred to the molecules in the electron-transporting layer 156. These functions prevent a decrease in emission efficiency.

For the hole-blocking layer 154, it is preferable to use a material having higher or comparative electron-transporting properties than hole-transporting properties and having a deeper HOMO level and a larger band gap than the molecules in the emission layer 150. Specifically, the difference between the HOMO level of the molecules included in the hole-blocking layer 154 and that of the molecules included in the emission layer 150 is preferred to be equal to or greater than 0.2 eV, 0.3 eV, or 0.5 eV. Furthermore, the difference between the band gap of the molecules included in the hole-blocking layer 154 and that of the molecules included in the emission layer 150 is preferred to be equal to or greater than 0.2 eV, 0.3 eV, or 0.5 eV. Specifically, a phenanthroline derivative, an oxadiazole derivative, a triazole derivative, a metal complex with a relatively large band gap (e.g., 2.8 eV or more) such as bis(2-methyl-8-quinolinolato) (4-hydroxy-biphenyl)aluminum, and the like are represented. The hole-blocking layer 154 may also have a single-layer structure or may be composed of a plurality of layers containing different materials. As mentioned above, the first buffer layer 148 preferably consists of the host material included in the emission layer 150 in the red-emissive light-emitting element 130-1. Accordingly, the difference in HOMO level between the first buffer layer 148 and the hole-blocking layer 154 is almost the same as the difference in HOMO level between the emission layer 150 and the hole-blocking layer 154 and is preferred to be equal to or greater than 0.1 eV and equal to or less than 0.5 eV or equal to or greater than 0.1 eV and equal to or less than 0.3 eV.

The hole-blocking layer 154 may also be provided so as to be shared by multiple pixels 120 (e.g., all of the pixels 120 of the display device 100). In this case, the hole-blocking layer 154 exists in the same layer between the pixels 120 (i.e., light-emitting elements 130) and is continuous without being divided between the pixels 120 (light-emitting elements 130). In addition, the hole-blocking layer 154 has the same composition and thickness between the pixels 120 (light-emitting elements 130).

### (9) Electron-Transporting Layer

The electron-transporting layer 156 functions to transport electrons injected from the counter electrode 134 to the emission layer 150 via the electron-injection layer 158. A (electron-accepting) compound which is easily reduced can be used for the electron-transporting layer 156. In other words, a compound with a shallow LUMO level can be used. For example, a metal complex containing a ligand with benzoquinolinol as a fundamental skeleton, such as tris(8-quinolinolato)aluminum and tris(4-methyl-8-quinolinolato)aluminum, a metal complex containing a ligand with oxadiazole or thiazole as a fundamental skeleton, and the like are exemplified. In addition to these metal complexes, a compound with an electron-deficient heteroaromatic ring, such as an oxadiazole derivative, a thiazole derivative, a triazole derivative, and a phenanthroline derivative may be used. The electron-transporting layer 156 may also have a single-layer structure or may be composed of a plurality of layers containing different materials.

Although not illustrated, similar to the hole-transporting layer 144, the electron-transporting layer 156 may be configured so that the thickness thereof increases in the order of the blue-emissive light-emitting element 130-3, the green-emissive light-emitting element 130-2, and the red-emissive light-emitting element 130-1. Thus, the electron-transporting layer 156 with a single-layer structure may be formed in the blue-emissive light-emitting element 130-3, the electron-transporting layer 156 with a two-layer structure may be formed in the green-emissive light-emitting element 130-2, and the electron-transporting layer 156 with a three-layer structure may be formed in the red-emissive light-emitting element 130-1, for example. Such a structure allows the formation of an appropriate resonator structure in each light-emitting element 130.

### (10) Electron-Injection Layer

For the electron-injection layer 158, a compound which promotes electron injection from the counter electrode 134 to the electron-transporting layer 156 can be used. For example, a mixture of a compound usable for the electron-transporting layer 156 and an electron donor such as lithium and magnesium may be used. Alternatively, an inorganic compound such as lithium fluoride and calcium fluoride may be used.

### 3. Structure of Pixel

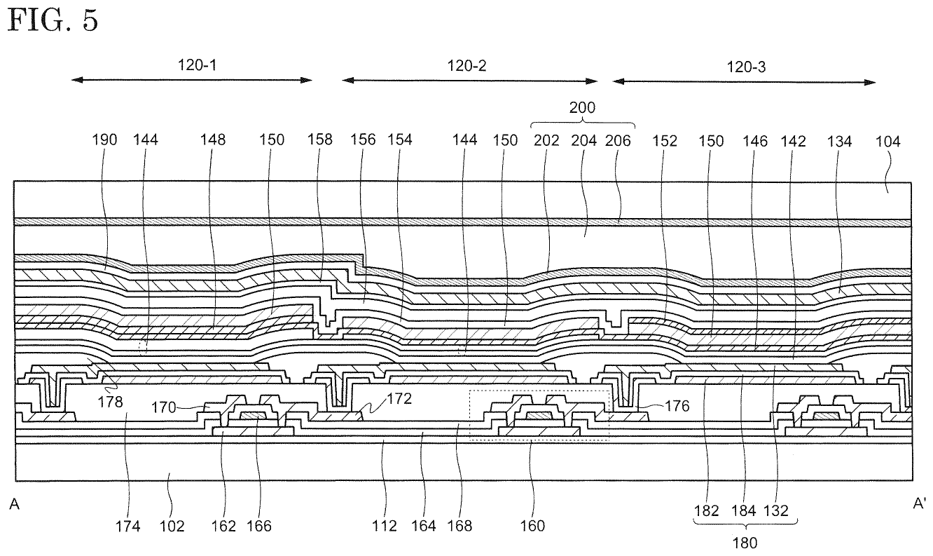

A schematic view of a cross section corresponding to the chain line A-A′ in FIG. 2 is shown in FIG. 5. In FIG. 5, the cross section of the continuously arranged red-emissive pixel 120-1, green-emissive pixel 120-2, and blue-emissive pixel 120-3 are schematically depicted, where the red-emissive light-emitting element 130-1, the green-emissive light-emitting element 130-2, and the blue-emissive light-emitting element 130-3 shown in FIG. 4 are respectively provided in the red-emissive pixel 120-1, the green-emissive pixel 120-2, and the blue-emissive pixel 120-3.

As described above, a pixel circuit is formed in each pixel 120 to drive the light-emitting element 130. The configuration of the pixel circuit may be determined arbitrarily, and any known configuration may be applied. In the example shown in FIG. 5, one transistor 160 electrically connected to the light-emitting element 130 and a capacitance element (auxiliary capacitance element) 180 connected to the transistor 160 are shown as a part of the elements constituting the pixel circuit. However, the pixel circuit may be configured with a plurality of transistors and a plurality of capacitance elements. Furthermore, although an example is demonstrated in which the light from the emission layer 150 is extracted through the counter substrate 104 in all of the light-emitting elements 130, the display device 100 may be configured so that the light from the emission layer 150 is extracted through the substrate 102.

### (1) Substrate and Counter Substrate

The substrate 102 and the counter substrate 104 are provided in order to provide physical strength to the display device 100 and to protect the plurality of pixels 120, the scanning-line driver circuits 106, and the signal-line driver circuit 108. The substrate 102 and the counter substrate 104 may be an inorganic material-containing substrate such as a crystalline semiconductor substrate, a glass substrate, and a quartz substrate or may contain a polymer such as a polyimide, a polyamide, and a polycarbonate. The substrate 102 and the counter substrate 104 may or may not be flexible. In the former case, the substrate 102 and/or the counter substrate 104 may be flexible sufficient to be elastically deformable or may be highly flexible sufficient to be plastically deformable. When the light emission from the light-emitting element 130 is extracted outside through the counter substrate 104, at least the counter substrate 104 is configured to transmit visible light. Conversely, when the light emission from the light-emitting element 130 is extracted outside through the substrate 102, at least the substrate 102 is configured to transmit visible light.

### (2) Pixel Circuit

As described above, since known configurations can be applied as the pixel circuit, a detailed description is omitted. In the example shown in FIG. 5, a transistor 160 functioning as a driving transistor is provided over the substrate 102. The transistor 160 may be provided directly over the substrate 102 or may be formed over the substrate 102 via an undercoat 112 for preventing the diffusion of impurities contained in the substrate 102. The transistor 160 shown in FIG. 5 is composed of a semiconductor film 162, a gate insulating film 164 over the semiconductor film 162, a gate electrode 166 over the gate insulating film 164, an interlayer insulating film 168 over the gate electrode 166, and a pair of terminals 170 and 172 provided over the interlayer insulating film 168 and electrically connected to the semiconductor film 162. Although the transistor 160 shown here is a top-gate type transistor, there is no restriction on the structure of the transistor 160, and a bottom-gate type transistor or a transistor having the gate electrodes over and below the semiconductor film may be used as the transistor 160.

A leveling film 174 is provided over the transistor 160 to absorb unevenness caused by the elements in the pixel circuit, such as the transistor 160, and provide a flat surface. Over the leveling film 174, a capacitance electrode 182, a capacitance insulating film 184 over the capacitance electrode 182, and the pixel electrode 132 over the capacitance insulating film 184 may be arranged, by which the auxiliary capacitance element 180 is structured. In this structure, the pixel electrode 132 is shared by the light-emitting element 130 and the auxiliary capacitance element 180. An opening is provided in the leveling film 174 to expose the terminal 172, and the pixel electrode 132 is electrically connected to the terminal 172 in this opening either directly or via a connecting electrode 176 covering this opening. A partition wall 178 which is an insulating film is provided to cover the edge of the pixel electrode 132, and the EL layer 140 and the counter electrode 134 are arranged to cover the pixel electrode 132 and the partition wall 178. With this structure, the adjacent light-emitting elements 130 are electrically insulated, and the EL layer 140 is prevented from being cut by the edge of the pixel electrode 132.

### (3) Other Components

As an optional component, one or a plurality of cap layers 190 may be provided over the counter electrode 134 to allow the light extracted from the counter electrode 134 to resonate and to improve color purity and luminance in the frontal direction. In addition, a protective film 200 may be provided over the light-emitting elements 130 to prevent impurities such as water and oxygen from entering the EL layer 140. The protective film 200 may be formed with a film containing a silicon-containing inorganic compound such as silicon nitride or a layer containing a polymer such as an acrylic resin and an epoxy resin, for example. For instance, the protective film 200 may be composed of a first layer 202 and a second layer 206 each containing silicon nitride as well as a layer containing a polymer provided therebetween as shown in FIG. 5.

Generally, each functional layer structuring the EL layer 140 is formed using an evaporation method. Therefore, metal masks are used to selectively arrange the functional layers in predetermined regions, and an increase in the number of metal masks directly leads to an increase in the manufacturing cost of display devices. However, in the display device 100, all or a part of the layers other than the emission layer 150, the first buffer layer 148, and the second buffer layer 152 can be formed simultaneously so as to be shared by all of the pixels 120 and to be continuous across all of the pixels 120. Thus, the hole-injection layer 142, the hole-blocking layer 154, the electron-blocking layer 146, the electron-transporting layer 156, and the electron-injection layer 158 can be formed over all of the pixels 120 using the same metal mask for example, in which pixel-by-pixel layer formation using a plurality of metal masks is not required. Furthermore, the first buffer layer 148 and the emission layer 150 of the red-emissive light-emitting element 130-1 can also be formed with the same metal mask, and the emission layer 150 of the blue-emissive light-emitting element 130-3 and the second buffer layer 152 can also be formed with the same metal mask. Therefore, implementation of an embodiment of the present invention prevents an increase in the manufacturing cost of display devices and enables the production of display devices at a lower cost.

However, it is relatively difficult to construct an appropriate carrier balance for the light-emitting elements 130, especially for the red-emissive light-emitting elements 130-1 and the green-emissive light-emitting elements 130-2 containing the thermally activated delayed fluorescence materials, and the carrier balance is greatly influenced by the structures of the electron-blocking layer 146 and the hole-blocking layer 154 located close to the emission layer 150. Therefore, if a structure is employed in which the electron-blocking layer 146 and the hole-blocking layer 154 are common across all of the light-emitting elements 130, the carrier balance of some of the light-emitting elements 130 is broken, which readily causes a decrease in efficiency, an increase in driving voltage, and a decrease in lifetime of the light-emitting elements 130.

However, in the display device 100 according to an embodiment of the present invention, the second buffer layer 152 is provided between the emission layer 150 and the hole-blocking layer 154 in the blue-emissive light-emitting element 130-3 as mentioned above. Furthermore, the first buffer layer 148 may also be provided between the electron-blocking layer 146 and the emission layer 150 in the red-emissive light-emitting element 130-1. Therefore, as experimentally proven in the Examples, an appropriate carrier balance can be achieved in all of the light-emitting elements 130. For example, even when the hole-blocking layer 154 and the electron-blocking layer 146 with optimized carrier balance for the green-emissive light-emitting element 130-2 is adopted in the red-emissive light-emitting element 130-1 and the blue-emissive light-emitting element 130-3, the formation of the first buffer layer 148 and the second buffer layer 152 enables the construction of an appropriate carrier balance in the red-emissive light-emitting element 130-1 and the blue-emissive light-emitting element 130-3. As a result, it is possible to provide the display device 100 with low power consumption, high efficiency, and high reliability at a low cost.

### 4. Modified Example

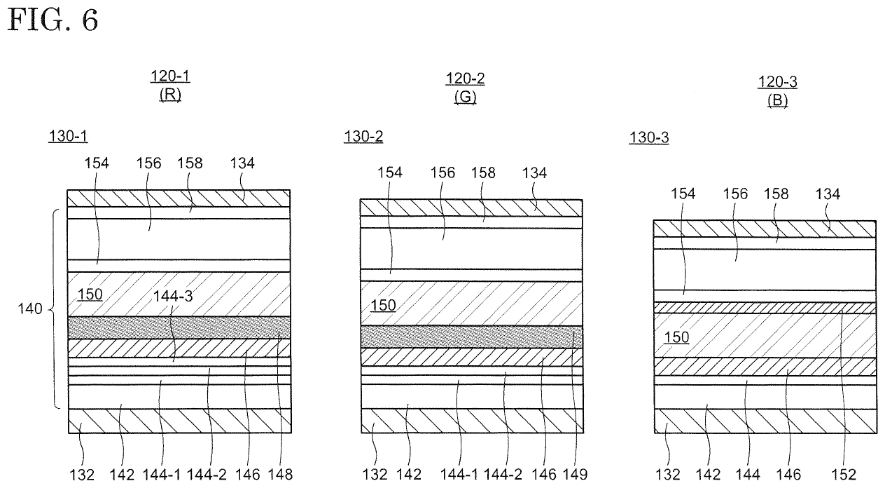

In the display device 100, a buffer layer may also be provided in the green-emissive light-emitting element 130-2. Specifically, a buffer layer (third buffer layer) 149 in direct contact with and between the electron-blocking layer 146 and the emission layer 150 may be arranged in the green-emissive light-emitting element 130-2 as shown in FIG. 6. The third buffer layer 149 contains the host material contained in the emission layer 150. In other words, the material contained in the third buffer layer 149 is identical to the host material contained in the emission layer 150. Preferably, the third buffer layer 149 consists of the host material and is substantially free of other components. The thickness of the third buffer layer 149 is also, for example, equal to or greater than 2.0 nm and equal to or less than 10 nm or equal to or greater than 2.0 nm and equal to or less than 8.5 nm. The use of the third buffer layer 149 to adjust the carrier balance of the green-emissive light-emitting element 130-2 improves the reliability of the green-emissive light-emitting element 130-2 without compromising its characteristics. In addition, since many functional layers (e.g., the hole-blocking layer 154, the electron-blocking layer 146, the electron-transporting layer 156, and the like) can be formed to be shared by all of the pixels 120, the number of deposition masks can be reduced, allowing the production of display devices at a lower cost. Note that, when the third buffer layer 149 is provided, the first buffer layer 148 may not be provided. For example, when the structures of the electron-blocking layer 146 and the hole-blocking layer 154 are optimized for the red-emissive light-emitting element 130-1 which does not have the first buffer layer 148, the first buffer layer 148 may not be provided, and the third buffer layer 149 may be selectively arranged in the green-emissive light-emitting element 130-2.

### 5. Manufacturing Method of Display Device

The display device 100 can be manufactured by sequentially depositing the functional layers over the substrate 102 having the pixel circuits and the pixel electrodes 132, which are fabricated by known methods. Specifically, the hole-injection layer 142 is formed over the pixel electrodes 132, provided over the substrate 102, by a spin-coating method, a dip-coating method, an inkjet method, or an evaporation method. Subsequently, the hole-transporting layer 144 and the electron-blocking layer 146 are formed sequentially by an evaporation method. When the hole-transporting layers are formed so that the thicknesses differ between the red-emissive light-emitting element 130-1, the green-emissive light-emitting element 130-2, and the blue-emissive light-emitting element 130-3, a metal mask exposing all of the pixels 120 may be used to form the first hole-transporting layer 144-1, a metal mask exposing the green-emissive pixel 120-2 and the red-emissive pixel 120-1 may be used to form the second hole-transporting layer 144-2, and a metal mask exposing the red-emissive pixel 120-1 may be used to form the third hole-transporting layer 144-3.

After this, the electron-blocking layer 146 is formed by an evaporation method. Since pixel-by-pixel layer formation is not required at this time, a metal mask exposing all of the pixels 120 is used to form the electron-blocking layer 146 over all of the pixels 120 at the same time.

An evaporation method is then utilized to form the emission layers of the red-emissive light-emitting element 130-1, the green-emissive light-emitting element 130-2, and the blue-emissive light-emitting element 130-3. At this stage, a metal mask exposing the red-emissive pixel 120-1, the green-emissive pixel 120-2, or the blue-emissive pixel 120-3 is used to perform the pixel-by-pixel formation of the emission layers 150. When the first buffer layer 148 is formed, a metal mask exposing the red-emissive pixel 120-1 may be used to form the first buffer layer 148 in the red-emissive pixel 120-1, and then the same mask may be used to form the emission layer 150. Similarly, when the third buffer layer 149 is formed, a metal mask exposing the green-emissive pixel 120-2 may be used to form the third buffer layer 149 in the green-emissive pixel 120-2, and then the same mask may be used to form the emission layer 150.

After that, a metal mask exposing the blue-emissive pixel 120-3 is used to form the second buffer layer 152 with an evaporation method. Therefore, the same metal mask can be used to continuously form the emission layer 150 and the second buffer layer 152 in the blue-emissive pixel 120-3, eliminating the need to replace or re-align the metal mask.

The hole-blocking layer 154, the electron-transporting layer 156, and the electron-injection layer 158 are then formed by an evaporation method. Since no pixel-by-pixel layer formation is required at this time, a metal mask exposing all of the pixels 120 may be used to simultaneously form the hole-blocking layer 154, the electron-transporting layer 156, and the electron-injection layer 158 in all of the pixels 120. However, when the electron-transporting layer 156 is formed so that the thickness varies among the pixels 120, the electron-transporting layer 156 may be formed pixel-by-pixel as appropriate, similar to the formation of the hole-transporting layer 144.

The counter electrode 134 is formed with an evaporation method or a sputtering method. For example, a counter electrode 134 containing an alloy of silver and magnesium may be formed by an evaporation method, while the counter electrode 134 containing ITO or IZO may be formed by a sputtering method.

As described above, at least the electron-blocking layer 146 and the hole-blocking layer 154 can be formed simultaneously in all of the pixels 120 by the manufacturing method of the display device 100 according to an embodiment of the present invention. Thus, it is possible to reduce the number of metal masks. Furthermore, as described above, even if the electron-blocking layer 146 with the same structure among all of the pixels 120 and the hole-block layer 154 with the same structure among all of the pixels 120 are formed, preferable carrier balance can be achieved in all of the pixels 120 by appropriately arranging the first buffer layer 148 to the third buffer layer 149. For example, even when the electron-blocking layer 146 and the hole-blocking layer 154, which are shared in all of the pixels 120 and are simultaneously formed in succession across all of the pixels 120, are optimized for the green-emissive light-emitting element 130-2, a preferable carrier balance can also be achieved in the red-emissive light-emitting element 130-1 and the blue-emissive light-emitting element 130-3 by forming the first buffer layer 148 and the second buffer layer 152. Alternatively, even when the electron-blocking layer 146 and the hole-blocking layer 154, which are shared in all of the pixels 120 and are simultaneously formed in succession across all of the pixels 120, are optimized for the red-emissive light-emitting element 130-1, a preferable carrier balance can also be achieved by forming the second buffer layer 152 and the third buffer layer 149 in the green-emissive light-emitting element 130-2 and the blue-emissive light-emitting element 130-3.

### Examples

### 1. Effects of First Buffer Layer on Red-Emissive Light-Emitting Element

A plurality of red-emissive light-emitting elements with different thicknesses of the first buffer layer (BL) (Examples) and two red-emissive light-emitting elements without the first buffer layer (Comparative Examples 1 and 2) were fabricated. In all of the light-emitting elements, ITO was used as the anode and a co-evaporated film of silver and magnesium was used as the cathode. The size of the emission region was 2.0 mm×2.0 mm. The emission layer contained a host material and a red-emissive thermally activated delayed fluorescence material, and lithium fluoride was used as the electron-injection layer. The configurations were the same between all of the light-emitting elements other than the structure of the electron-blocking layer and the thickness of the first buffer layer. The thicknesses of the functional layers structuring the EL layer are shown in Table 1. Here, the light-emitting element of the Comparative Example 1 is an element with an electron-blocking layer optimized for a red-emissive light-emitting element, while the light-emitting elements of the Comparative Example 2 and the Examples are elements having an electron-blocking layer used in light-emitting elements containing a green-emissive thermally activated delayed fluorescence material.

TABLE 1
Thickness of EL layers of red-emissive light-emitting elements
of the example and the comparable examples (nm)

| | Hole- | Hole- | Electron- | First | | Hole- | Electron- | Electron- |
|---|---|---|---|---|---|---|---|---|
| | injection | transporting | blocking | buffer | Emission | blocking | transporting | injection |
| Element | layer | layer | layer | layer | layer | layer | layer | layer |
| Example | 17 | 60 | 5 | 2.5-10 | 35 | 10 | 20 | 2 |
| Comparable | 17 | 60 | 5 | 0 | 35 | 10 | 20 | 2 |
| example 1 | | | | | | | | |
| Comparable | 17 | 60 | 5 | 0 | 35 | 10 | 20 | 2 |
| example 2 | | | | | | | | |

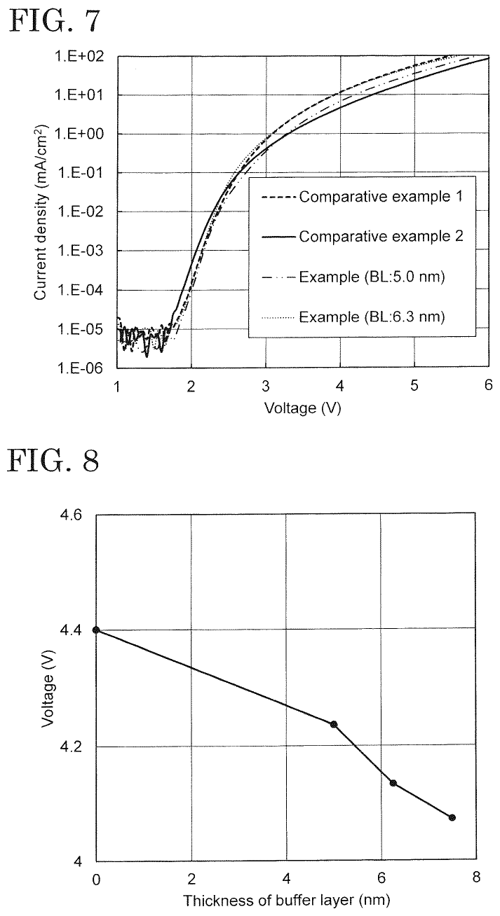

The voltage-current density curves of the fabricated light-emitting elements are shown in FIG. 7. Comparing the Comparative Example 1 with the Comparative example 2, it can be seen that the voltage-current density curve shifts to the high voltage side when the material of the electron-blocking layer is changed. This result suggests that the change in electron-blocking properties generates an internal electric field caused by the carriers (electrons) accumulated at the interface between the electron-blocking layer and the emission layer, which changes the carrier balance and increases the driving voltage of the light-emitting element. However, as in the light-emitting element in the example, the carriers are diffused by providing the first buffer layer. As a result, the voltage-current density curve shifts to the low-voltage side, resulting in a voltage-current density characteristic close to that of the Comparative Example 1. This result suggests that the carrier balance can be improved by the first buffer layer even if a non-optimized electron-blocking layer is used.

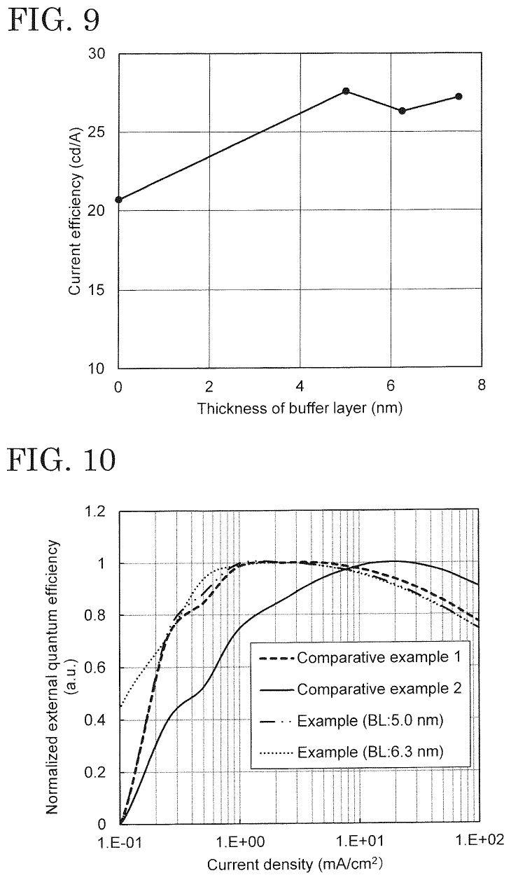

This fact is also suggested by FIG. 8 and FIG. 9. FIG. 8 is a plot showing the relationship between the driving voltage and the thickness of the first buffer layer of the light-emitting elements of the Comparative Example 2 and the Examples and indicates that the driving voltage decreases with increasing thickness of the first buffer layer. FIG. 9 is a plot showing the relationship between the current efficiency and the thickness of the first buffer layer of the light-emitting elements of the Comparative Example 2 and the Examples and indicates that the current efficiency increases with increasing thickness of the first buffer layer. It is also suggested that the effect saturates as the thickness of the first buffer layer approaches 8 nm.

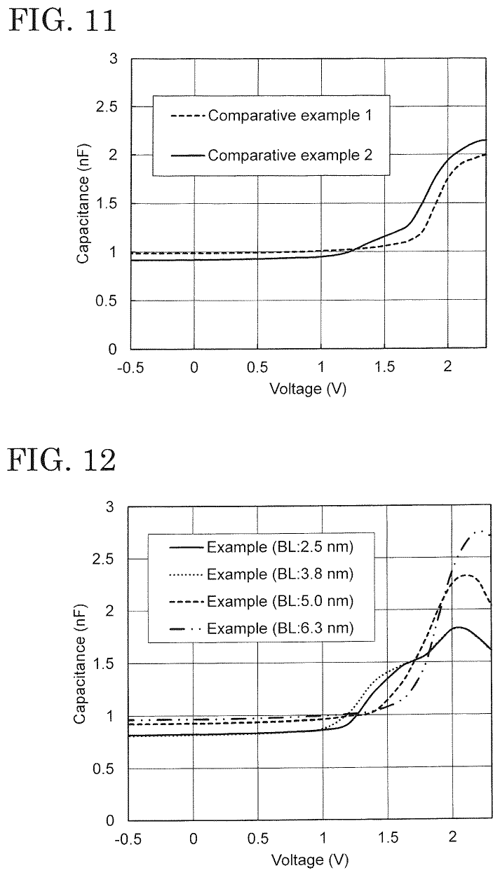

FIG. 10 shows a plot of current density versus normalized external quantum efficiency. It can be readily understood from the comparison between the Comparative Example 1 and the Comparative Example 2 that, when the first buffer layer is not optimized, there is a significant decrease in the normalized external quantum efficiency, especially in the low current-density region. This result suggests that the carrier balance is greatly disrupted and the contribution of non-radiative recombination increases at a low current density, i.e., at a low driving voltage. The non-radiative recombination corresponds, for example, to the generation of exciplexes and light absorption by polarons. In contrast, it can be seen from FIG. 11 that the plot approaches the plot of the Comparative Example 1 especially in the low current density region, and the normalized external quantum efficiency is improved by providing the first buffer layer and increasing its thickness. It is also understood from these results that, even when a non-optimized electron-blocking layer is used, its influence can be suppressed, and characteristics similar to or better than those of the light-emitting elements containing an optimized electron-blocking layer can be obtained by providing the first buffer layer.

Voltage-capacitance plots of the light-emitting elements of the Comparative Examples 1 and 2 obtained by impedance spectroscopy are shown in FIG. 11. Comparison of the Comparative Examples 1 and 2 reveals that, when the electron-blocking layer is not optimized, the capacitance increases at low voltages. This result indicates that, in the state where the electron-blocking layer is not optimized, carriers accumulate in the EL layer, especially at the interface between the electron-blocking layer and the emission layer, from the initial stage of driving, resulting in a relatively large internal electric field. In contrast, as can be understood from FIG. 12, the increase in capacitance in the low-voltage region is eliminated as the thickness of the first buffer layer increases in the light-emitting elements of the Examples, showing a tendency to approach the plot of the light-emitting element of the Comparative Example 1. These results also indicate that the first buffer layer improves the carrier balance, suppresses the generation of an internal electric field, and lowers the driving voltage. Furthermore, the capacitance in the high-voltage region increases inversely. These results suggest that the carriers used for recombination increase to improve efficiency. In other words, even if the structure of the electron-blocking layer is changed in the red-emissive light-emitting element, the influence thereof can be suppressed by the first buffer layer.

### 2. Influence of Second Buffer Layer on Blue-Emissive Light-Emitting Element

A plurality of blue-emissive light-emitting elements with different thicknesses of the second buffer layer (Examples) and a blue-emissive light-emitting element without the second buffer layer (Comparative Example 3) were fabricated. In all of the light-emitting elements, ITO was used as the anode, and a co-evaporated film of silver and magnesium was used as the cathode. The size of the emission region was 2.0 mm×2.0 mm. The emission layers in the Examples and the Comparative Example 3 contained a host material and a blue-emissive fluorescence material which does not exhibit thermally activated delayed fluorescence, and lithium fluoride was used as the electron-injection layer. The second buffer layer was formed by independently evaporating the host material contained in the emission layer alone. The configurations were identical among all of the light-emitting elements except for the thickness of the second buffer layer. The thicknesses of the functional layers structuring the EL layer are shown in Table 2. Here, the light-emitting element of the Comparative Example 3 is an element having a hole-blocking layer optimized for a red-emissive light-emitting element without the first buffer layer.

TABLE 2
Thicknesses of EL layers of blue-emissinve light-emitting
elements of the example and the comparable example (nm)

| | Hole- | Hole- | Electron- | First | | Hole- | Electron- | Electron- |
|---|---|---|---|---|---|---|---|---|
| | injection | transporting | blocking | buffer | Emission | blocking | transporting | injection |
| Element | layer | layer | layer | layer | layer | layer | layer | layer |
| Example | 17 | 100 | 5 | 20 | 1.0-5.0 | 10 | 30 | 2 |
| Comparable | 17 | 100 | 5 | 20 | 0 | 10 | 30 | 2 |
| example 3 | | | | | | | | |

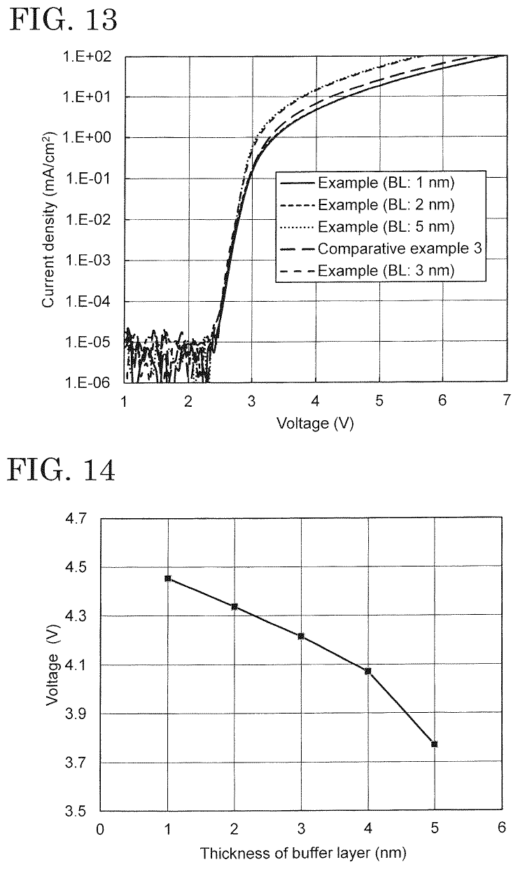

Voltage-current density curves of the fabricated light-emitting elements are shown in FIG. 13. Compared with the Comparative Example 3, although the voltage-current characteristics are almost the same as those of the Comparative Example 3 in the case where the thickness of the second buffer layer is approximately 1 nm, it was confirmed that the voltage-current density curve shifts to the low-voltage side as the thickness of the second buffer layer increases from 2 nm. This result suggests that in the Comparative Example 3, an internal electric field is generated by the carriers (holes) accumulated at the interface between the hole-blocking layer and the emission layer to change the carrier balance and increase the driving voltage of the light-emitting element. However, as in the light-emitting elements of the Examples, the carriers are diffused by providing the second buffer layer. As a result, the voltage-current density curve shifts to the low-voltage side, indicating that the light-emitting elements can be driven at a lower voltage than in the Comparative Example 3. From these results, it is suggested that the carrier balance can be improved by the second buffer layer even if a non-optimized hole-blocking layer is used.

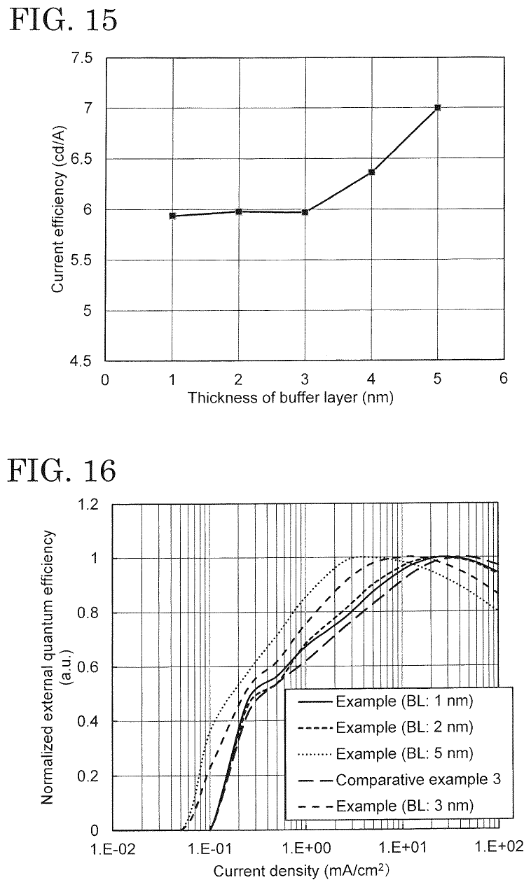

This fact is also suggested by the relationships of the driving voltage and the current efficiency with respect to the thickness of the second buffer layer in the blue-emissive light-emitting elements of the Comparative Example 3 and the Examples shown in FIG. 14 and FIG. 15, respectively. As shown in these drawings, as the thickness of the second buffer layer increases, the driving voltage decreases and the current efficiency increases. It can also be found from these results that the carrier balance is improved by providing the second buffer layer, and in particular, power consumption is significantly reduced when the thickness of the second buffer layer exceeds 3 nm.

Similar results were also obtained in the relationship between the current density and the normalized current efficiency of the blue-emissive light-emitting elements of the Comparative Example 3 and the Examples. As shown in FIG. 16, in the case of the Comparative Example 3 and the case where the thickness of the second buffer layer is small (e.g., 1 nm), there is a significant decrease in normalized current efficiency, especially in the low current-density region. This result suggests that the carrier balance is greatly disrupted and the contribution of non-radiative recombination increases at a low current density, i.e., at low driving voltages. Non-radiative recombination corresponds, for example, to the generation of exciplexes and light absorption by polarons. In contrast, it is understood from FIG. 16 that, compared with the plot of the Comparative Example 3, the normalized current efficiency in the low current density region is improved by providing the buffer layer and increasing its thickness (e.g., 2 nm or more). From these results, it can also be understood that, even when a non-optimized hole-blocking layer is used, its influence can be suppressed by providing the second buffer layer, and characteristics similar to or better than those of a light-emitting element containing an optimized hole-blocking layer can be obtained.

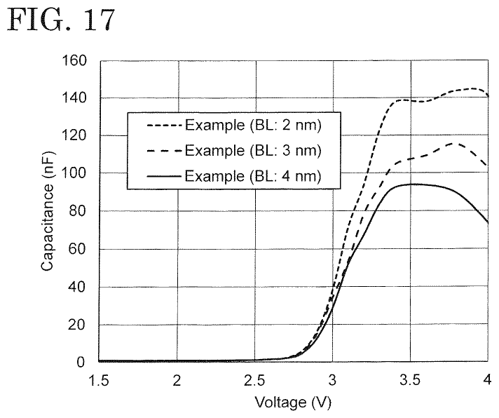

The voltage-capacitance plots of the blue-emissive light-emitting elements of the Comparative Example 3 and the Examples obtained by impedance spectroscopy are shown in FIG. 17. In the case of the Comparative Example 3 and the case where the thickness of the second buffer layer is small (e.g., 2 nm), the capacitance increases, and this tendency is especially remarkable particularly at low voltages. This tendency indicates that, in the state where the hole-blocking layer is not optimized, carriers accumulate in the EL layer, especially at the interface between the hole-blocking layer and the emission layer, from the initial stage of driving, and a relatively large internal electric field is generated. In contrast, in the light-emitting elements of the Examples, the increase in capacitance in the low-voltage region is eliminated as the thickness of the buffer layer increases. These results also indicate that the buffer layer improves the carrier balance, suppresses the generation of an internal electric field and lowers the driving voltage. Furthermore, the capacitance in the high-voltage region is also reduced. These results suggest that carriers used for recombination increase to further improve the carrier balance, and recombination occurs more efficiently. This result also indicates that, even if the structure of the hole-blocking layer is changed in the blue-emissive light-emitting element, the influence thereof can be suppressed by the second buffer layer.

As described above, although extremely high emission efficiency can be obtained in light-emitting elements containing thermally activated delayed fluorescence materials, it is not always easy to construct an optimal carrier balance, and in particular, the carrier balance is strongly influenced by the carrier-blocking layers (hole-blocking layer and electron-blocking layer). Hence, when applying light-emitting elements containing thermally activated delayed fluorescence materials in full-color displays which require three primary colors, it is necessary to independently adjust the optimal carrier-blocking layers for each of the red-emissive light-emitting element, the green-emissive light-emitting element, and the blue-emissive light-emitting element. This requirement causes an increase in the evaporation process requiring the so-called pixel-by-pixel layer formation, resulting in a significant increase in the manufacturing cost of display devices.

However, in the display device according to an embodiment of the present invention, even if the same structure is applied to the carrier-blocking layers in the light-emitting elements arranged in all of the pixels with different emission colors, It is possible to construct an appropriate carrier balance in all of the light-emitting elements by providing the second buffer layer 152 or by providing both the second buffer layer 152 and the first buffer layer 148. Therefore, the increase in the evaporation process requiring the pixel-by-pixel layer formation can be suppressed, and display devices with low power consumption and high reliability can be produced at a low cost.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A display device comprising a first pixel, a second pixel, and a third pixel respectively comprising a first light-emitting element, a second light-emitting element, and a third light-emitting element configured to emit red light, green light, and blue light, respectively,
wherein each of the first light-emitting element, the second light-emitting element, and the third light-emitting element comprises:
a pixel electrode;
an electron-blocking layer over the pixel electrode;
an emission layer over the electron-blocking layer;
a hole-blocking layer over the emission layer; and
a counter electrode over the hole-blocking layer,
the third light-emitting element further comprises a first buffer layer between the emission layer and the hole-blocking layer,
the emission layers of the first light-emitting element and the second light-emitting element include a thermally activated delayed fluorescence material, and
the emission layer of the third light-emitting element includes a first fluorescence material having a fluorescence lifetime equal to or longer than 1 ps and shorter than 1 ns.

2. The display device according to claim 1,
wherein the electron-blocking layer and the hole-blocking layer each exist in the same layer across the first light-emitting element, the second light-emitting element, and the third light-emitting element.

3. The display device according to claim 1,
wherein the fluorescence lifetime of the thermally activated delayed fluorescence material is equal to or longer than 1 ns.

4. The display device according to claim 1,
wherein at least one of the emission layers of the first light-emitting element and the second light-emitting element further includes a second fluorescence material having a fluorescence lifetime equal to or longer than 1 ps and shorter than 1 ns.

5. The display device according to claim 1,
wherein the first light-emitting element further comprises a second buffer layer between the electron-blocking layer and the emission layer.

6. The display device according to claim 1,
wherein the second light-emitting element further comprises a third buffer layer between the electron-blocking layer and the emission layer.

7. The display device according to claim 5,
wherein the emission layer of the first light-emitting element further includes a first host material, and
the second buffer layer consists of the first host material.

8. The display device according to claim 6,
wherein the emission layer of the second light-emitting element further includes a second host material, and
the third buffer layer consists of the second host material.

9. The display device according to claim 1,
wherein the emission layer of the third light-emitting element further includes a third host material, and
the first buffer layer consists of the third host material.

10. The display device according to claim 1,
wherein a difference in lowest unoccupied molecular orbital level between the emission layer and the first buffer layer is equal to or greater than 0.1 eV and equal to or less than 0.3 V in the third light-emitting element.

11. The display device according to claim 1,
wherein a difference in lowest unoccupied molecular orbital level between the first buffer layer and the electron-blocking layer is equal to or greater than 0.1 eV and equal to or less than 0.3 V in the third light-emitting element.

12. The display device according to claim 1,
wherein a difference in highest occupied molecular orbital level between the emission layer and the first buffer layer is equal to or greater than 0.1 eV and equal to or less than 0.3 V in the third light-emitting element.

13. The display device according to claim 1,
wherein a difference in highest occupied molecular orbital level between the first buffer layer and the electron-blocking layer is equal to or greater than 0.1 eV and equal to or less than 0.3 V in the third light-emitting element.

14. The display device according to claim 1,
wherein a thickness of the first buffer layer is equal to or greater than 2 nm and equal to or less than 8.5 nm.

15. The display device according to claim 5,
wherein a difference in highest occupied molecular orbital level between the second buffer layer and the hole-blocking layer is equal to or greater than 0.1 eV and equal to or less than 0.3 V in the first light-emitting element.

16. The display device according to claim 5,
wherein a thickness of the second buffer layer is equal to or greater than 1 nm and equal to or less than 7 nm.

17. The display device according to claim 8,
wherein a thickness of the third buffer layer is equal to or greater than 1 nm and equal to or less than 7 nm.
